(19) United States
(12) Patent Application Publication
(10) Pub. No.: US 2014/0308811 A1
(43) Pub. Date: Oct. 16, 2014

(54) SEMICONDUCTOR INTEGRATED-CIRCUIT DEVICE AND METHOD OF PRODUCING THE SAME

(71) Applicant: IBARAKI UNIVERSITY, Mito-shi (JP)

(72) Inventors: Yasushi SASAJIMA, Hitachi (JP); Jin OONUKI, Hitachi (JP); Suguru TASHIRO, Hitachi (JP); Khyou Pin KHOO, Perak (MY)

(73) Assignee: IBARAKI UNIVERSITY, Mito-shi (JP)

(21) Appl. No.: 14/256,580

(22) Filed: Apr. 18, 2014

Related U.S. Application Data
(62) Division of application No. 13/132,454, filed on Feb. 17, 2012, now abandoned.

(30) Foreign Application Priority Data
Dec. 4, 2008 (JP) 2008-309890

(51) Int. Cl. H01L 21/768

(52) U.S. Cl. CPC H01L 21/76883
USPC 438/660

(57) ABSTRACT

A semiconductor integrated-circuit device using the copper wiring having increased electromigration resistance, low resistivity, and a line width of 70 nm or less, is provided. The present invention is characterized by the annealing treatment wherein a copper wiring having a line width of 70 nm or less is heated with a heating rate of 1K to 10K per second, and then the temperature is constantly maintained for a prescribed time duration.

### TECHNICAL FIELD

The present invention relates to a semiconductor integrated-circuit device, and specifically relates to a semiconductor integrated-circuit device having highly durable copper wiring and a method of producing the semiconductor integrated-circuit devices.

### BACKGROUND OF THE INVENTION

Integration of a semiconductor integrated-circuit device has been rapidly increased as indicated by the Moore's Law that describes the number of components per chip increases four times every three years. An indication for the increase in the number of components per chip is the International Technology Roadmap for Semiconductor. Taking an example of the wiring of the ITRS 2005 Edition MPU (Micro Processing Unit), the target width of wiring necessary to increase the number of components per chip was 90 nm in 2005, 68 nm in 2007, 45 nm in 2010, and will be 32 nm in 2013; and to ensure high-speed motion, the target resistivity was 3.07 μΩcm, 3.43 μΩcm, 4.08 μΩcm, and will be 4.83 μΩcm, respectively.

Inexpensive and relatively low resistivity aluminum or aluminum alloys have been used for wiring material of the semiconductor integrated-circuit device. However, as the number of components per chip increases (i.e. the width of wiring decreases), aluminum tends to be replaced with copper or copper alloys that have resistivity of approximately half that of aluminum and an allowable current more than two-digits greater than aluminum. On the other hand, in addition to low resistivity, the wiring of the semiconductor integrated-circuit device requires high reliability that means high electromigration resistance. To increase electromigration resistance of copper wiring, various methods have been proposed: a method described in JP 05-315327A in which a copper film is formed while irradiating low-energy ions (10 to 120 eV), and then the copper film is heat-treated at a temperature of 180° C. or higher, thereby obtaining copper wiring which has the grain size being equal to or more than 10 times of the line width (1 μm or less); a method described in JP 11-186261A in which the grain size is increased from 0.9 μm to 2.0 μm by annealing treatment wherein after a copper wiring has been formed, the copper wiring is heated at a temperature between 300° C. and 500° C. with a heating rate of 20° C. per minute or less, and then the temperature is maintained for 5 to 2000 seconds; and a method described in JP 2008-198933A in which current density is increased from 3 mA to 20 mA from the middle stage to the later stage of the electrolytic plating process to increase the rate of copper film formation, thereby making the grain size of the middle and upper portions of the wiring larger than that of the lower portion of the wiring.

As a method of forming copper micro wiring, the method called a damascene method is known. The damascene method requires at least a groove forming process for embedding the wiring, a deposition process for forming a metal diffusion prevention layer, metal seed layer, metal wiring layer, and polishing arrest film, a photolithography process, an etching process, and a polishing process. As the above-mentioned deposition method for forming a metal wiring layer, various kinds of methods have been used as described in JP 11-186261A, JP 2008-198933A, JP2008-270250A, JP 06-275617 A, JP 09-306912A, and JP 2006-24754A, such as PVD (Physical Vapor Deposition) methods including a sputtering method and the like, electrolytic or nonelectrolytic plating techniques, or CVD (Chemical Vapor Deposition) methods using organic metal materials. JP 11-186261A, JP 2008-270250A to JP 2006-24754A disclose that increasing the average crystal grain size of the copper wiring layer is effective for decreasing resistivity of the copper wiring layer as well as increasing electromigration resistance. In addition, JP 06-275617A discloses the production apparatuses for semiconductor devices which make the content ratio of the (111) surface, i.e. the densest surface of the copper crystal, high in order to increase oxidation resistance and which control the grain size in forming copper wiring by means of a sputtering method. Furthermore, JP 09-306912A discloses that improving the orientation of metal in wire can increase electromigration resistance of a semiconductor element.

### SUMMARY OF THE INVENTION

Since technologies disclosed in patent JP 05-315327A and JP 11-186261A are specifically for copper wiring having a line width of 1 μm (1000 nm) or 0.5 μm (500 nm), and the crystal grain size is greatly affected by a line width, those technologies are not readily applicable to the wiring having a line width of 70 nm or less. Specifically, JP 11-186261A describes a method in which substrates are placed in a heat treatment chamber at a temperature of 300° C. or lower to suppress void generation caused by rapid heating, and then the temperature is increased at a rate of 20° C. per minute. Although the technology disclosed in JP 11-186261A is effective for suppressing voids, it was found that the technology is not effective for coarsening the crystal grain size of copper and controlling the crystal grain size in terms of the growth of copper crystals. JP 2008-198933A describes a method which decreases a crystal grain size in an area of wire, e.g. the area near the top surface adjacent to other metal film of the copper wiring, to increase electromigration resistance, thereby enabling high resistivity. This technology does not enable low resistivity of copper wiring and is not effective for increasing electromigration resistance.

Furthermore, JP 2008-270250A to JP 2006-24754A describe various methods of increasing the grain size of the copper crystal; however, production conditions are difficult to control and the size of the device is also limited. Therefore, it was difficult to enable the mass production of semiconductor devices having both micro copper wiring and a high reliability. The technology disclosed in JP 2008-270250A requires a highly-pure plating bath that is not commercially available and copper electrodes, and it also has problems such that a long annealing time is required to stably control the grain size of the copper crystal for a desired size. Because the technologies disclosed in JP 06-275617A and JP 09-306912A are production methods that use a sputtering method and a CVD method, the size of the device is limited and the production conditions must be precisely controlled. A method of forming copper wiring by a nonelectrolytic plating technique described in JP 2006-24754A uses a temperature of 400° C. or higher for annealing treatment; therefore, it is desired that the heating temperature be lower and heating time be shorter for mass production at low costs.

The inventors of the present invention realized that in order to produce a semiconductor integrated-circuit device that is highly reliable even when the width of wiring becomes 70 nm or less, the electromigration resistance must be further increased and resistivity must become lower. Furthermore, as a method of mass-producing semiconductor integrated-circuit devices having high electromigration resistance and low resistivity, it is necessary to establish a method that enables heat treatment at a lower temperature and with shorter time than conventional methods.

An objective of the present invention is to produce copper wiring having increased electromigration resistance and low resistivity and provide semiconductor integrated-circuit devices using the copper wiring.

Another objective of the present invention is to provide a method of mass-producing semiconductor integrated-circuit devices equipped with copper wiring having high electromigration resistance and low resistivity at low costs.

Other objectives of the present invention will be clarified by descriptions of the examples.

To achieve the above objectives, according to one aspect of the present invention, the semiconductor integrated-circuit device according to the present invention comprises a semiconductor substrate with a circuit element formed thereon, an insulation layer formed on the main surface of the semiconductor substrate, a trench formed by at least using the insulation layer, and a copper wiring formed within the trench, wherein the width of the copper wiring is 70 nm or less, and the average crystal grain size of the wiring surface is 1.15 times or more of the average crystal grain size of a copper wiring obtained by annealing in a usual method (the copper wiring is heated in a hydrogen gas at a temperature from 20° C. to 300° C. with a heating rate of 0.156K per second, and the temperature of 300° C. is maintained for 30 minutes). By doing so, it is possible to produce a copper wiring having high electromigration resistance, low resistivity, and a line width of 70 nm or less. It is verified that electromigration resistance can be increased when the width of wiring is up to 20 nm, however, it is presumed that electromigration resistance can also be increased when the width of wiring is less than 20 nm. Furthermore, in addition to the fact that the average crystal grain size can be 1.15 times or more of the average crystal grain size obtained by annealing in a usual method, it is possible to significantly increase electromigration resistance by making the width of the distribution of the grain size of the copper wiring expressed as Δd/dₐᵥ 1.2 or less, more preferably 1.2 to 0.3, where dₐᵥ is the average crystal grain size, and Δd is the width of the crystal grain size defined as the difference between the maximum crystal grain size dₘₐₓ and the minimum crystal grain size dₘᵢₙ. Furthermore, it is possible to increase the ratio of the densest crystalline orientation face and obtain the stable copper metal texture by making the ratio of the (111) oriented crystal grain on the surface of the copper wiring 1.1 times or more than that obtained in such a way that the copper wiring is heated in a hydrogen gas to a prescribed temperature within 300° C. to 500° C. from 20° C. with a heating rate of 0.156K per second, and the prescribed temperature is maintained for 30 minutes. Thus, it is possible to produce the wiring with low resistivity and high electromigration resistance steadily.

Furthermore, a semiconductor integrated-circuit device according to claim 1 is obtained in such a way that a wiring layer of a copper wiring is deposited on a semiconductor substrate by a plating technique, then the semiconductor substrate is placed in an atmosphere of 200° C. or lower, heated to a prescribed temperature within 200° C. to 500° C., more preferably within 250° C. to 400° C., with a heating rate of 1K per second or more, and after the temperature has been increased, the prescribed temperature is maintained for a prescribed time duration within one minute to 60 minutes; and the average crystal grain size of the surface of the copper wiring is 1.15 times or more of the average crystal grain size of a copper wiring obtained in such a way that the copper wire is heated in a hydrogen gas at temperature from 20° C. to 300° C. with a heating rate of 0.156K per second, and the temperature of 300° C. is maintained for 30 minutes. Moreover, it is possible to make the resistivity of the wiring low and significantly increase electromigration resistance by making the width of the distribution of the grain size of the copper wiring expressed as Δd/dₐᵥ 1.2 or less, and making the ratio of the (111) oriented crystal grain of the copper wire 1.1 times or more larger than that obtained in such a way that the copper wiring is heated in a hydrogen gas to a prescribed temperature within 300° C. to 500° C. from 20° C. with a heating rate of 0.156K per second, and the prescribed temperature is maintained for 30 minutes.

To achieve the above objectives, according to one aspect of the present invention, a method of producing semiconductor integrated-circuit devices according to the present invention is a method of producing a semiconductor integrated-circuit device comprising a semiconductor substrate with a circuit element formed thereon, an insulation layer formed on the main surface of the semiconductor substrate, a trench formed by at least using the insulation layer, and a copper wiring formed within the trench; and has an annealing process wherein the copper wiring is heated to a prescribed temperature (500° C. or lower, more preferably 400° C. or lower) with a heating rate of 1K per second or more, and after the temperature has been increased, the prescribed temperature is maintained (maintaining constant temperature) for a prescribed time duration. By doing so, it is possible to make the average crystal grain size of the wiring surface of the copper wiring having a width 70 nm or less 1.15 times or more of the average crystal grain size of a copper wiring obtained by annealing in a usual method. Furthermore, by setting the upper limit of the heating rate at 10K per second, it is possible to reduce peeling-off of the copper wiring and deterioration of performance of the semiconductor integrated-circuit device. Moreover, since it is more preferable as the average crystal grain size becomes larger, there is no upper limit of the value of the ratio of the average crystal grain size to the average crystal grain size of copper wiring obtained by annealing in a usual method.

Furthermore, to achieve the above objectives, according to one aspect of the present invention, in a method of producing a semiconductor integrated-circuit device according to the present invention, a wiring layer of the copper wiring is deposited by a plating technique, then the semiconductor substrate is placed in an atmosphere at 200° C. or lower, heated to a prescribed temperature within 200° C. to 500° C., more preferably 250° C. to 400° C., with a heating rate of 1K per second or more, and then the prescribed temperature is maintained for a prescribed time duration within one minute to 60 minutes. The upper limit of the heating rate is set at 10K per second in order to reduce peeling-off of copper wiring and deterioration of performance of the semiconductor integrated-circuit device.

Also, to achieve the above objectives, according to another aspect of the present invention, a method of producing semiconductor integrated-circuit devices according to the present invention is a method of producing a semiconductor integrated-circuit device comprising a semiconductor substrate with a circuit element formed thereon, an insulation layer formed on the main surface of the semiconductor substrate, a trench formed by at least using the insulation layer, and a copper wiring formed within the trench; and has an annealing process wherein the copper wiring is heated to a prescribed temperature by a temperature gradient of 30K to 55K per μm between the bottom portion and the top surface, and then the prescribed temperature is maintained for a prescribed time duration. By doing so, it is possible to make the average crystal grain size of the copper wiring having a line width 70 nm or less 1.15 times or more of the average crystal grain size obtained by annealing in a usual method.

Also, to achieve the above objectives, according to another aspect of the present invention, a method of producing semiconductor integrated-circuit devices according to the present invention is a method of producing a semiconductor integrated-circuit device comprising a semiconductor substrate with a circuit element formed thereon, an insulation layer formed on the main surface of the semiconductor substrate, a trench formed by at least using the insulation layer, and a copper wiring formed within the trench; and has an annealing process wherein a wiring layer of the copper wiring is deposited by a plating technique, then the semiconductor substrate is placed in an atmosphere at 200° C. or lower, and the copper wiring is heated to a prescribed temperature within 200° C. to 500° C., more preferably 250° C. to 400° C., by a temperature gradient of 30K to 55K per μm between the bottom portion and the top surface with a heating rate of 1K to 10K per second or more, and then the prescribed temperature is maintained for a prescribed time duration within one minute to 60 minutes. This method makes it possible to make the average crystal grain size of the copper wiring having a line width of 70 nm or less 1.15 times or more of the average crystal grain size obtained by annealing in a usual method.

Furthermore, to achieve the above objectives, according to another aspect of the present invention, in a method of producing a semiconductor integrated-circuit device according to the present invention, heating with a heating rate of 1K per second or more is conducted by irradiation by a lamp and/or laser, more specifically by irradiation by an infrared lamp.

According to the present invention, it is possible to produce copper wiring in which the average crystal grain size is 1.15 times or more larger than that obtained by annealing treatment in a usual method and the line width is 70 nm or less. Thus, it is possible to produce a semiconductor integrated-circuit device having a high electromigration resistance, low resistivity, high reliability, and a long service life. Furthermore, it is possible to facilitate the production of highly reliable and long-life semiconductor integrated-circuit devices. By doing so, it is possible to produce wiring for semiconductor integrated-circuit devices that satisfy the specification proposed in the International Technology Roadmap for Semiconductor by mass-production stably at low costs.

### BRIEF DESCRIPTION OF THE DRAWINGS

FIG. 1 is a schematic cross-sectional diagram of a semiconductor integrated-circuit device shown as an example of the present invention.

FIGS. 2A and 2B illustrate surface EBSP images showing the comparison of the average crystal grain size between the copper wiring produced by the present invention and by the conventional copper wiring.

FIG. 3 is a schematic diagram of a polycrystal model used for the simulation of heat treatment of the copper wiring.

FIG. 4 illustrates a characteristic curve showing the relationship between the heating rate and the ratio of the crystal grain size when the copper wiring is annealed.

FIG. 5 is a schematic process chart explaining the changes of the crystal state when copper wiring is annealed by high and low heating rates.

FIG. 6 illustrates the relationship between the ratio of average crystal grain size of the wiring surface and the resistance value in a 70 nm width of copper wiring.

FIG. 7 is a schematic diagram showing the temperature distribution in the calculating area used for the simulation of heat treatment.

FIG. 8 illustrates four regions of the inside of the wiring used for the analysis of the simulation of heat treatment.

FIG. 9 illustrates the relationship between the temperature gradient within wiring and the width of grain size distribution when copper wiring is annealed.

FIGS. 10A-10G are a schematic process chart explaining an example of a method of producing semiconductor integrated-circuit devices according to the present invention.

### DETAILED DESCRIPTION OF THE PREFERRED EMBODIMENTS

The best embodiment of the present invention is a method of producing semiconductor integrated-circuit devices that adopts the copper wiring annealing process wherein the bottom (under) surface side and the top surface side of the copper wiring are heated by a temperature gradient of 30K to 55K per μm so that the temperature of the top surface side becomes higher than that of the bottom (under) surface side, and with a heating rate of 1K to 10K per second, and then a prescribed temperature is constantly maintained. More specifically, the best embodiment of the present invention is a method of producing semiconductor integrated-circuit devices that adopts the annealing process wherein after the wiring layer of the copper wiring has been deposited by a plating technique, the above-mentioned semiconductor substrate is placed in an atmosphere of 200° C. or lower, and while the temperature gradient of 30K to 55K per μm is maintained between the bottom portion and the top surface of the copper wiring, the semiconductor substrate is heated to a temperature of 200° C. to 500° C. with a heating rate of 1K to 10K per second, more preferably heated to a prescribed temperature within the range between 250° C. and 400° C.; and then the above-mentioned prescribed temperature is maintained for a prescribed time within the range between one minute and 60 minutes.

Hereafter, preferred embodiments of a semiconductor integrated-circuit device according to the present invention and a method of producing the semiconductor integrated-circuit device are described in detail with reference to the drawings.

### EXAMPLE 1

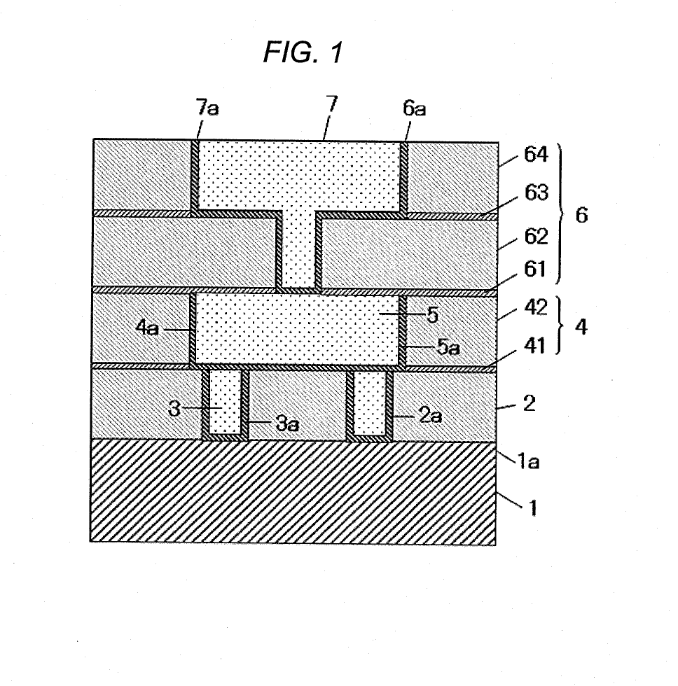

FIG. 1 is a schematic cross-sectional diagram of a semiconductor integrated-circuit device according to the present invention. Although the number of wiring layers of an actual semiconductor integrated-circuit device is 8, 9, or more, to simplify an explanation, the example shows a 2-layer wiring structure. In the drawing, the number 1 represents a semiconductor substrate on which a large number of circuit elements (not shown) are formed adjacent to one main surface 1a of the substrate; the number 2 represents a first insulation layer, composed of e.g. a silicon oxide layer, formed on one main surface 1a of the semiconductor substrate 1; the number 2a represents a through-hole formed in the first insulation layer 2; the number 3 represents a plug, composed of e.g. tungsten, formed within the through-hole 2a; 3a represents a barrier layer, composed of e.g. TiN (titanium nitride), formed between the through-hole 2a and the plug 3; the number 4 represents a second insulation layer, composed of e.g. a silicon oxide layer 42, formed via a silicon nitride layer 41 on the first insulation layer 2 and the plug 3; the number 4a represents a first trench formed in the second insulation layer 4; the number 5 represents a first copper wiring formed within the first trench 4a; the number 5a represents a barrier layer, composed of e.g. TaN (tantalum nitride)/Ta (tantalum), formed between the first trench 4a and the first copper wiring 5; the number 6 represents a third insulation layer formed by sequentially laminating e.g. a silicon oxide layer 62, a silicon nitride layer 63, and a silicon oxide layer 64 via e.g. a silicon nitride layer 61 on the second insulation layer 4 and the first copper wiring 5; the number 6a represents a second trench having a T-letter shaped cross section formed on the third insulation layer 6; the number 7 represents a second copper wiring formed within a second trench 6a; and the number 7a represents a barrier layer, composed of e.g. Ta/TaN/Ta, formed between the second trench 6a and the second copper wiring 7. The average crystal grain size of the first copper wiring 5 and/or the second copper wiring 7 is 1.15 times or more than the average crystal grain size of the copper wiring obtained by annealing in a usual method (wherein copper wiring is heated in a hydrogen gas at a temperature from 20° C. to 300° C. with a heating rate of 0.156K per second and then the temperature of 300° C. is maintained for 30 minutes).

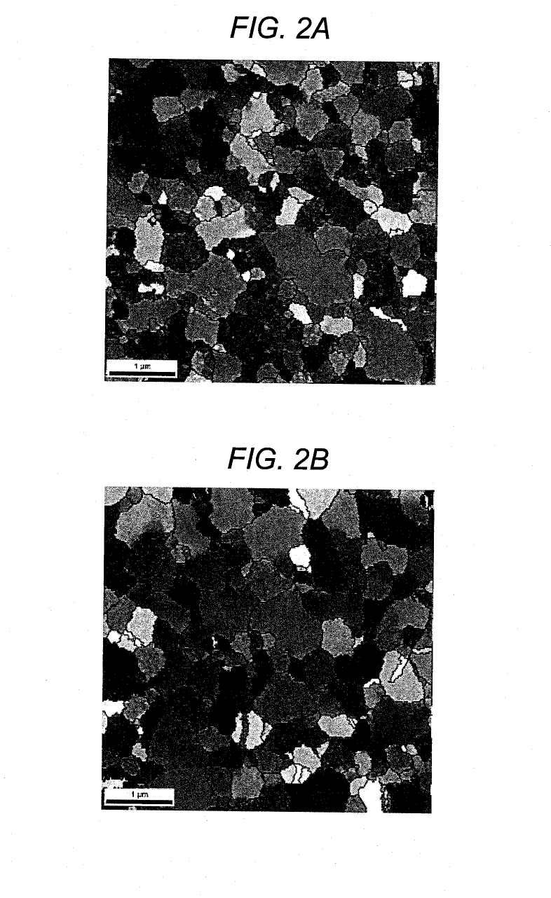

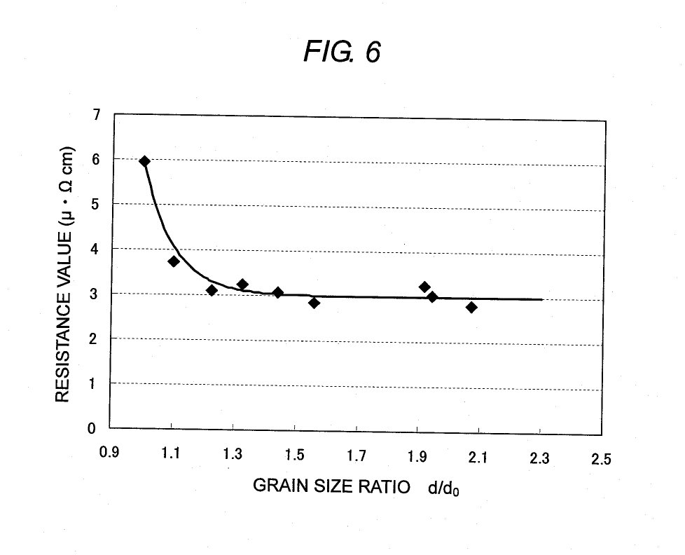

The reason why the average crystal grain size of the copper wiring is made 1.15 times or more than that of the copper wiring obtained by annealing in a usual method will be described. After copper wiring used for a semiconductor integrated-circuit device has been formed within a trench, for example by nonelectrolytic plating, the copper wiring is annealed in order to remove strain, increase adhesion with barrier layers and increase the crystal grain size. The heating rate during the annealing treatment currently being conducted is about 0.156K per second in usual methods, and the value of 20° C. per minute (0.333K per second) disclosed in JP 11-186261A is exceptional. Experiments confirm that setting the heating rate at 1K per second or more can increase the average crystal grain size. The anneal treatment used for the experiments is as follows: In a usual method, heating was conducted by resistive heating in a hydrogen gas flow at a temperature from 20° C. to 300° C. with a heating rate of 0.156K per second, and then the temperature of 300° C. was maintained for 30 minutes. In a rapid heating method, heating was conducted by infrared heating in a vacuum at a temperature from 20° C. to 300° C. with a heating rate of 1.3K per second and 6.3K per second, and then the temperature of 300° C. was maintained for five minutes. The experimental results obtained by the use of copper solid film layers are shown in Table 1 and FIG. 2. FIG. 2A illustrates an EBSP (Electron Backscattering Pattern) image of the copper wiring surface that has been annealed by a usual method, and FIG. 2B illustrates an EBSP image of the copper wiring surface that has been annealed by a rapid heating method with a heating rate of 1.3K per second. As the result of the usual annealing treatment, many micro crystal grains remain as indicated by arrows in FIG. 2A. On the contrary, FIG. 2B indicates that a considerable number of micro crystal grains disappeared as the result of annealing treatment by the rapid heating method. Thus, as shown in Table 1, it is verified that the annealing treatment by the rapid heating method can increase the average grain size. Results shown in Table 1 and FIG. 2 were obtained by the use of copper solid film layers. It is verified that the average grain size becomes smaller than that of the solid film when the copper wiring is formed within a trench, but the average grain size obtained by the rapid heating method is still larger than the average grain size obtained by the usual method (see FIG. 6 that is shown later in this document).

TABLE 1
Relationship between the heating rate and
the average crystal grain size

| | |
|---|---|
| Usual method | Rapid heating method |

| | | | |
|---|---|---|---|
| Heating rate | 0.156 | 1.3 | 6.3 |
| (K/sec) | | | |
| Average crystal | 292 | 351 | 336 |
| grain size | | | |
| (nm) | | | |

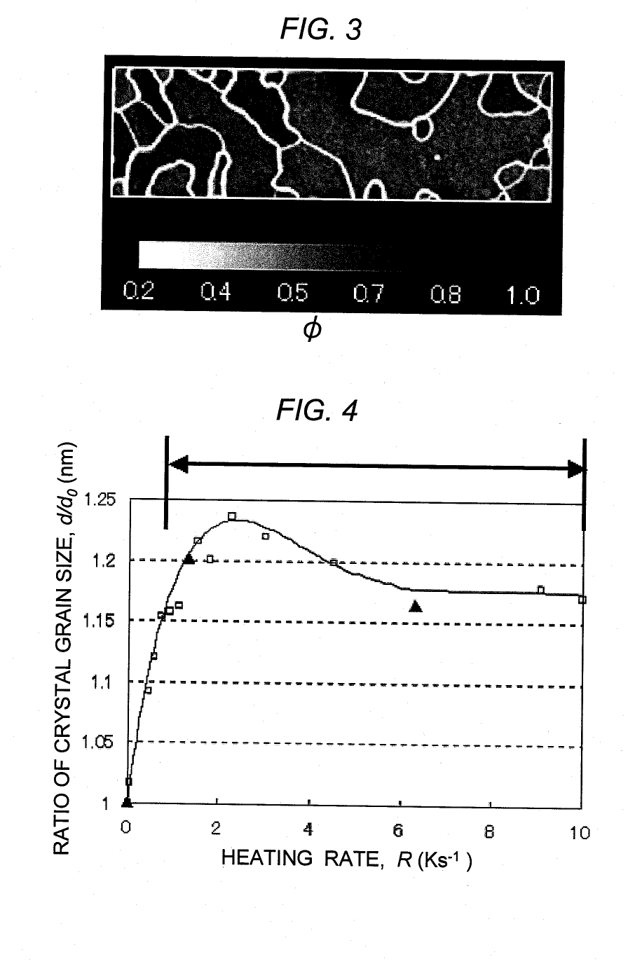

Simulation of heat treatment was conducted to complement the experimental results shown in Table 1. A phase field method that is effective for analyzing time evolution of mesoscale material texture was adopted as a simulation method, and the model that uses phase field φ and crystal orientation field θ proposed by Kobayashi-Warren et al. (A. Warren, R. Kobayashi, A. E. Lobkovsky and W. C. Carter: Acta Mater. 51 (2003) 6035-6058) was adopted as a model for a polycrystalline system. In this model, phase field φ indicates the crystallinity, and crystal orientation field θ indicates the rotational azimuth (radian) of crystal. The value 0 of the phase field φ indicates noncrystal, and the value 1 of the phase field φ indicates perfect crystal. The state of perfect crystal does not actually appear, but usually, the value φ of 0.5 to 0.7 indicates the value within the crystal grain, and the value φ of 0.2 to 0.4 indicates the value of the crystal grain boundary. FIG. 3 shows an example of calculated phase field φ. This drawing corresponds to the cross section of the wiring of the semiconductor integrated-circuit device, measuring 1.32 μm high and 4.41 μm wide. The crystal grain boundary is indicated by white lines as a low crystallinity area, and the area enclosed within the white lines becomes one crystal grain. The area of a crystal grain is obtained, and let the value be equal to the area of a virtual perfect-circular crystal grain, then the radius r of the circular crystal grain is obtained, and the value 2r is defined as a crystal grain size. The average value of the grain size of all crystal grains is called the “average crystal grain size.”

In FIG. 4, the relationships between a heating rate and a ratio of the crystal grain size obtained by experiments and the simulation are plotted in the same coordinates, wherein the filled triangles (▴) indicate experimental values and the open squares (□) indicate simulation values. A ratio of the crystal grain size means a ratio d/d₀ that is a ratio of the average crystal grain size d obtained by annealing treatment in a rapid heating method to the average crystal grain size d₀ obtained by annealing treatment in a usual method. This drawing shows that the experimental values are approximate to the simulation values, which indicates that the simulation method is appropriate. The drawing also shows that the ratio of the crystal grain size significantly changes as the heating rate changes in 1K per second or less, which indicates that controlling the ratio of the crystal grain size is unstable. When the heating rate is from 1K per second to 10K per second, the ratio of the crystal grain size is as high as 1.15 or more, and fluctuation of the ratio of the crystal grain size to the fluctuation of the heating rate is small. Therefore, this indicates that copper wiring in which the average crystal grain size is large can be stably obtained. When the heating rate becomes 10K per second or more, strain that occurs in a silicon substrate increases, causing the copper wiring to peel off or increasing the cause of deterioration of performance of the semiconductor integrated-circuit device, which is undesirable. Accordingly, it is preferable that the heating rate during annealing treatment be from 1K per second to 10K per second.

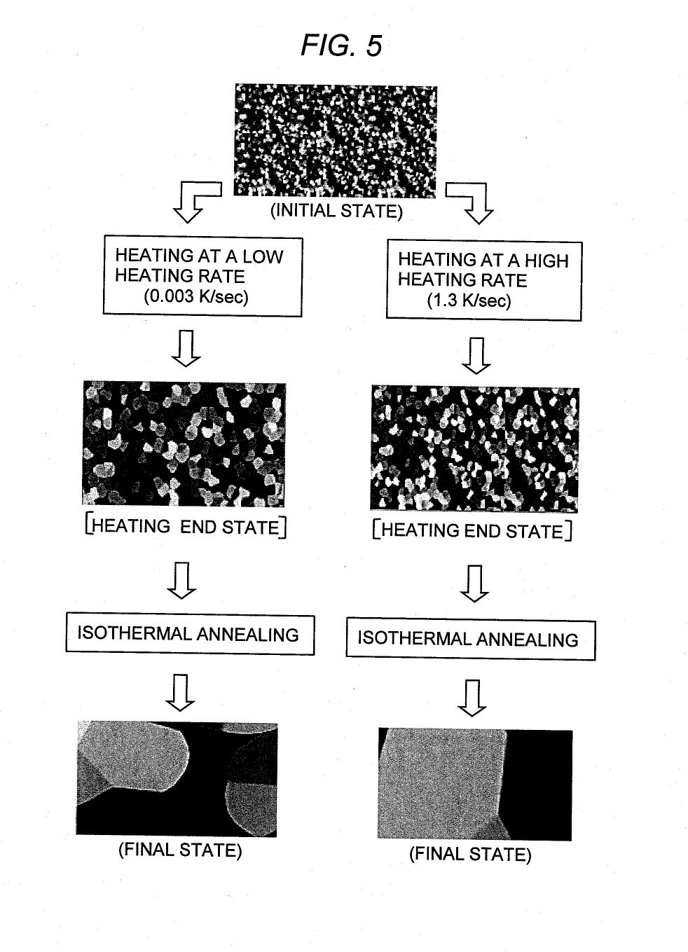

According to FIG. 5, description will be given about why the average crystal grain size increases when copper wiring is rapidly heated at a heating rate of 1K per second or more as shown in FIG. 4. When annealing treatment starts, the specimen are in the same initial state where crystal grains are very fine. At the end of heating stage, crystal grains heated at a low heating rate are slightly coarser than crystal grains heated at a high heating rate; and by the subsequent isothermal annealing, crystal grains heated at a high heating rate become slightly coarser than crystal grains heated at a low heating rate. Heating at a low heating rate (0.156K per second) causes the coalescence of crystal grains, however, time duration of heating at low temperature is prolonged due to the low heating rate. Consequently, grains with comparatively large anisotropy therebetween start to coalesce together, causing boundaries with large orientational difference to disappear. Furthermore, the grain growth resulted in decrease in the area of grain boundaries, and interface energy at the end of heating stage is low. For this reason, crystal grains will not become coarse in isothermal annealing even at high temperature. When heating is conducted at a high heating rate (1.3K per second), adjacent crystal grains with a small orientation difference coalesce together at the heating stage, while grain boundaries with comparatively large orientation difference remain, and crystal grains grow up to a certain size while interface energy remains comparatively high. Since isothermal annealing is performed in the state in which crystal grains are comparatively large and interface energy is high, it is considered that the ratio of interface energy consumed by the coalescence of grains is low and crystal grains are effectively coarsened. Therefore, to coarsen crystal grains, it is considered effective to conduct heating at a heating rate at which interface energy required for the grain growth is not consumed and to a certain extent the coalescence of crystal grains can progress at the heating stage.

FIG. 6 shows the relationship between the grain size ratio d/d₀ and the resistance value of the copper wiring, where the grain size ratio is defined as the ratio of the average crystal grain size (d) of the wiring surface in the copper wiring width of 70 nm to the average crystal grain size (d₀) of the copper wiring obtained by annealing treatment in a usual method, in which resistive heating is conducted at a heating rate of 0.156K per second in a hydrogen gas by a usual method. This drawing indicates that the value 1.15 is considered as a border; when the grain size ratio d/d₀ becomes less than 1.15, the resistance value rapidly increases; and when the grain size ratio d/d₀ becomes 1.15 or more, the resistance value becomes as low as 3.0 μΩ·cm. This resistance value is significantly lower than that of the target resistance values of 3.43 μΩ·cm, 4.08 μΩ·cm, and 4.83 μΩ·cm when the width of the wiring is 68 nm, 45 nm, and 32 nm, respectively, as described in the International Technology Roadmap for Semiconductor 2005 edition. The present invention is characterized by the use of copper wiring having a grain size ratio d/d₀ of 1.15 or more where the resistance value is sufficiently low and almost constant. The data shown in FIG. 6 was taken from the measurements when the channel width is 70 nm. When the channel width is 50 nm or 30 nm, the resistance value is slightly larger than the value in the case of the channel width being 70 nm; accordingly, both the characteristic curve and the resistance values in FIG. 6 are shifted in parallel in an upward direction. Thus, it was verified that in the both cases, the inflection point, from which the resistance decrease range in the characteristic curve shifts to the resistance stable range, is located where the grain size ratio is around 1.15.

Also, in the semiconductor integrated-circuit device having a wiring width of 70 nm shown in FIG. 6, generation of voids in the copper wiring layer was not observed, and the time duration until the semiconductor integrated-circuit device becomes 50% defective becomes longer than that in the case of the above-mentioned usual method (heating rate of less than 1K per second), which verifies excellent reliability. Thus, it was found that the semiconductor integrated-circuit device according to the present invention also has excellent electromigration resistance. Moreover, the reason why a void was not generated on the copper wiring layer in the semiconductor integrated-circuit device according to the present invention is that the plating bath components and the plating production conditions in the electrolytic plating technique were optimized within technological common knowledge. In the present invention, under the conditions where the heating rate is up to 10K per second, generation of such voids that may affect characteristics and reliability of the semiconductor integrated-circuit device was not observed. However, when the heating rate exceeds 10K per second, even though the plating method or annealing conditions are optimized, the copper wiring is easily peeled off, and the generation of such voids that will deteriorate the performance of the semiconductor integrated-circuit device cannot be ignored.

### EXAMPLE 2

A copper solid film was produced in the same method as example 1 except for adopting another rapid heating method in which infrared heating in a vacuum was conducted to heat the sample from 20° C. to 400° C. with a heating rate of 1.3K per second, and the temperature was maintained at 400° C. for one minute. With regard to this copper solid film layer, the ratio of the (111) oriented copper crystal grains was compared to that obtained by a usual method. Annealing conditions in a usual method is that a copper solid film is deposited by an electrolytic plating technique, heated by resistive heating in a hydrogen gas flow from 20° C. to 400° C. with a heating rate of 0.156K per second, and then left in the atmosphere at 400° C. for 30 minutes. The ratio of the (111) oriented copper crystal grains obtained by the rapid heating method according to the present invention was 86%, while that obtained by the above-mentioned usual method was 73%. The ratio of the former was 1.18 times the ratio of the latter.

Furthermore, a copper solid film was made in the same conditions except for changing the annealing temperature, which is set after the heating process, from 400° C. to 500° C. With regard to the copper solid film layer, the ratio of the (111) oriented copper crystal grains was compared between the rapid heating method according to the present invention and a usual method. The ratio of the (111) oriented copper crystal grains obtained by the rapid heating method according to the present invention was 89%, while that obtained by the above-mentioned usual method was 80%. The ratio of the former was 1.11 times larger than that of the latter. Furthermore, with regard to the copper solid film made under the same conditions except for changing the annealing temperature, which is set after the heating process, from 400° C. to 300° C., the ratio of the (111) oriented copper crystal grains was compared with the ratio obtained by a usual method. The ratio of the former was 1.18 times or more larger than that of the latter. When annealing temperature was 300° C., the multiplying factor of the ratio of the (111) oriented copper crystal grains obtained from the comparison between the rapid heating method and the usual method tends to become slightly larger than the multiplying factor in the case of the annealing temperature being 400° C. or 500° C. This is because isothermal annealing temperatures somehow affect the growth of the (111) oriented copper crystal grains.

Thus, in the method according to the present invention, the ratio of the (111) oriented copper crystal grains is 1.1 times or more larger than that obtained by the usual method, and the densest copper crystal formation ratio is high. Consequently, it is possible to make resistivity of wiring low and significantly increase electromigration resistance.

The above examples 1 and 2 adopt a rapid heating method, wherein infrared heating in a vacuum is conducted to heat the sample from 20° C. to 300° C. or 400° C. with a heating rate of 1.3K per second and/or 6.3K per second, and then the temperature of 300° C. is maintained for five minutes or the temperature of 400° C. is maintained for one minute. However, the present invention is not intended to be limited to those conditions. As long as prescribed conditions can be realized with the heating rate within a range from 1K per second to 10K per second as the heating method, the methods that uses an ordinary high temperature bath, high temperature plate, or the like, or a method that uses irradiation by an infrared lamp or infrared laser, can be adopted. Among these methods, it is preferable to use a lamp and/or laser for irradiation that can locally heat a selected portion in order to precisely control the heating rate, and when considering both the ease of temperature control and the economics of heating device, irradiation by infrared lamp is preferable. Furthermore, the heating process can be conducted not only in a vacuum but also in an atmosphere selected from hydrogen, argon, and nitrogen. The present invention can adopt a method of utilizing an atmosphere that does not allow oxygen to mix in and facilitates the control of the heating rate during growing crystals of the copper-wiring layer. In the present invention, the starting temperature of heating process is not limited to room temperature, but any temperature can be set for an objective of the present invention as long as the temperature is lower than the temperature used later in the high-temperature annealing process.

The present invention is characterized in that the high heating rate at 1K per second or more can lower the temperature used for the subsequent isothermal annealing process and can reduce the time duration of the annealing process. However, in terms of the growth of copper crystals, it is necessary to set the heating temperature at a prescribed temperature or higher in order to increase the crystal grain size of the copper wiring layer and control the width of the crystal grain size. Moreover, to reduce the above-mentioned annealing time, it is preferable that the heating temperature is high. To do so, the present invention sets the temperature used for the isothermal annealing process at 200° C. to 500° C., and more preferably at a prescribed temperature between 250° C. and 400° C. in order to achieve an objective of the present invention to facilitate the production of semiconductor integrated-circuit devices. Furthermore, the time duration for the isothermal annealing adopted in the present invention can be shortened to one minute to achieve an objective of the present invention. Therefore, it is possible to reduce damage that tends to occur during high temperature treatment of the semiconductor integrated-circuit device. In the present invention, the time duration for isothermal annealing can be set at a prescribed time within one minute to 60 minutes so as to control the growth of copper crystals and reduce damage to the semiconductor integrated-circuit device. That is, the annealing process according to the present invention is a process in which a semiconductor substrate with a deposited copper wiring layer is placed in an atmosphere set at 200° C. or lower; heated to a prescribed temperature between 200° C. and 500° C., more preferably between 250 to 400° C., with a prescribed heating rate of 1K per second or more, more preferably within 1K to 10K per second; and then the above prescribed temperature is maintained for a prescribed time within one minute to 60 minutes.

Since annealing in the rapid heating method is conducted with a high heating rate, and there is a temperature difference between the bottom (under) surface side and the top surface side even when the thickness of the copper wiring is at an nm level, the annealing treatment naturally has a temperature gradient. Since annealing in the usual method is conducted with a conventional low heating rate, and there is no temperature difference between the bottom (under) surface side and the top surface side, the annealing treatment does not have a temperature gradient. When comparing the width of the vertical distribution of the grain size of copper wiring obtained by those two types of annealing methods, as shown in Table 2, it is found that the annealing treatment with a temperature gradient can reduce the width of the distribution of the grain size. Table 2 shows the measurement results obtained by the use of the copper wiring with 70 nm width. Herein, the temperature difference ΔT is an estimated value in a one-dimensional thermal conduction model, and the maximum grain size dₘₐₓ, minimum grain size dₘᵢₙ, width of the grain size Δd, average grain size dₐᵥ, and the width of grain size distribution Δd/dₐᵥ were evaluated from individual grain size values by a method similar to the simulation described below. Furthermore, rapid heating shown in Table 2 corresponds to the condition where the heating rate is 1.7K per second, and the adoption of this heating rate enables the control of the temperature difference ΔT and the temperature gradient dT/dL at the values shown in Table 2.

TABLE 2
Width of the grain size distribution obtained by the usual annealing
technique and the annealing technique with a temperature gradient

| | Temperature | Temperature | Maximum | Minimum | Width of | Average | Width of |
|---|---|---|---|---|---|---|---|
| | difference | gradient | grain size | grain size | grain size | grain size | grain size |
| Annealing | ΔT | dT/dL | dₘₐₓ | dₘᵢₙ | Δd | dₐᵥ | distribution |
| technique | (K) | (K/μm) | (nm) | (nm) | (nm) | (nm) | Δd/dₐᵥ |
| Usual | 0 | 0 | 135 | 25 | 110 | 70 | 1.57 |
| method | | | | | | | |
| Rapid | 45 | 34 | 125 | 45 | 80 | 84.5 | 0.947 |
| heating | | | | | | | |

The results shown in Table 2 indicate that in order to reduce the width of the distribution of the grain size and obtain uniform size crystal grains, conducting heat treatment with a temperature gradient between the top surface and the under surface of copper wiring is effective.

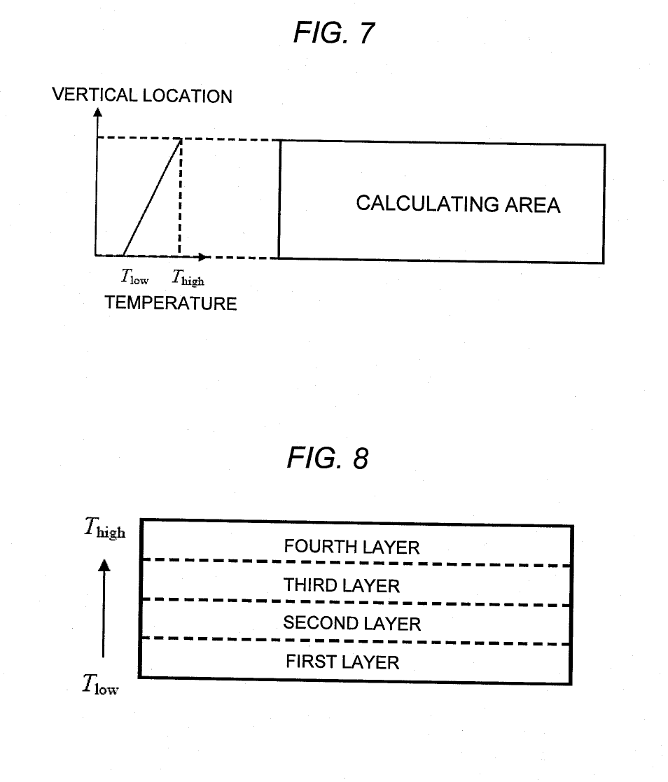

Which range of the temperature gradient between the top surface and the under surface of copper wiring is effective for equalizing the size of crystal grains was confirmed by simulating heat treatment. By the use of calculation parameters of copper, different temperatures are set for the upper calculating area and the lower calculating area as shown in FIG. 7, and to make the temperature distribution therebetween becomes a straight line, the distribution of temperatures within the calculating area is determined. Simulation was conducted by a computer in which a constant temperature was maintained for 666 seconds in the area for which temperature distribution was thus determined. To analyze the obtained simulation result, the area within the wiring was divided into four sections as shown in FIG. 8, and the distribution of crystals in each area was analyzed. The maximum grain size dₘₐₓ in Table 2 indicates the average grain size of the fourth layer in FIG. 8, and the minimum grain size dₘᵢₙ indicates the average grain size of the first layer. Furthermore, the average grain size dₐᵥ indicates the average value of the entire area of the wiring. Since the fourth layer is located on the high temperature side, the average grain size is the largest among the four layers; and since the first layer is located on the low temperature side, the average grain size is the smallest among the four layers. The width of the grain size Δd is defined as dₘₐₓ−dₘᵢₙ. The value Δd/dₐᵥ obtained by dividing the width of the grain size Δd by the average grain size dₐᵥ of the entire area is defined as the width of the distribution of the grain size.

Moreover, in FIG. 8, simulation was conducted by dividing the copper wiring into four sections between the top surface and the under surface, however, the number of partitions is not intended to be limited to four and may be three or five.

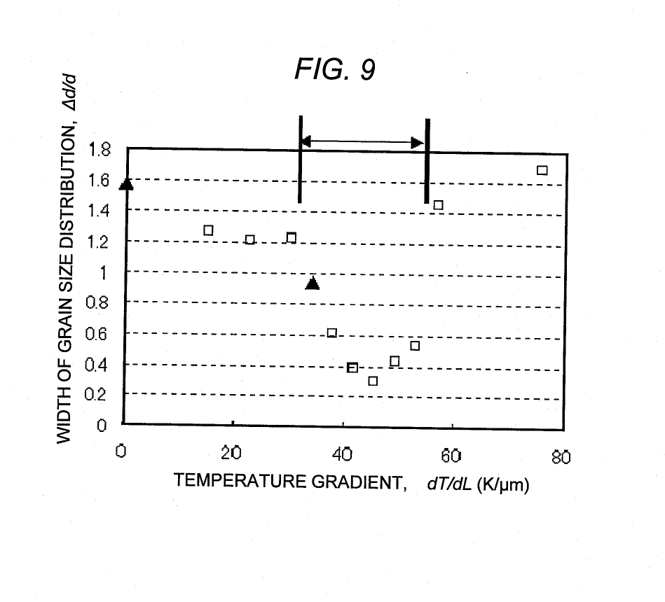

In FIG. 9, the relationship between the temperature gradient between the top surface and the under surface of the copper wiring and the width of the distribution of the grain size is shown in the same coordinates by the use of the actual measurements of the width of the distribution of the grain size and the simulation values shown in Table 2, wherein the filled triangles (▴) indicate the experimental values and the open squares (□) indicate the simulation values, respectively. The figure indicates that the actual measurements agree well with the simulation values, which indicates that the simulation method is appropriate. The figure also shows that by providing the temperature gradient of 30 to 55 (K per μm) between the top surface and the under surface of the copper wiring, it is possible to keep the value of the width of the distribution of the grain size, which is an index of variation in average grain size, 1.2 or less. When a temperature gradient is provided between the top surface and the under surface of the copper wiring, a difference in the distribution of the grain boundary energy arises from the top surface toward the under surface. With using this energy difference as a driving force, the growth of grains is accelerated further than the condition in which a temperature gradient is not provided. However, if a temperature gradient is made too large, the temperature on the under surface becomes too low and the growth of grains is inhibited, resulting in increasing the width of the distribution of the grain size. Therefore, the temperature gradient of 30 to 55 (K per μm) is effective for equalizing the distribution of the crystal grain size.

### EXAMPLE 3

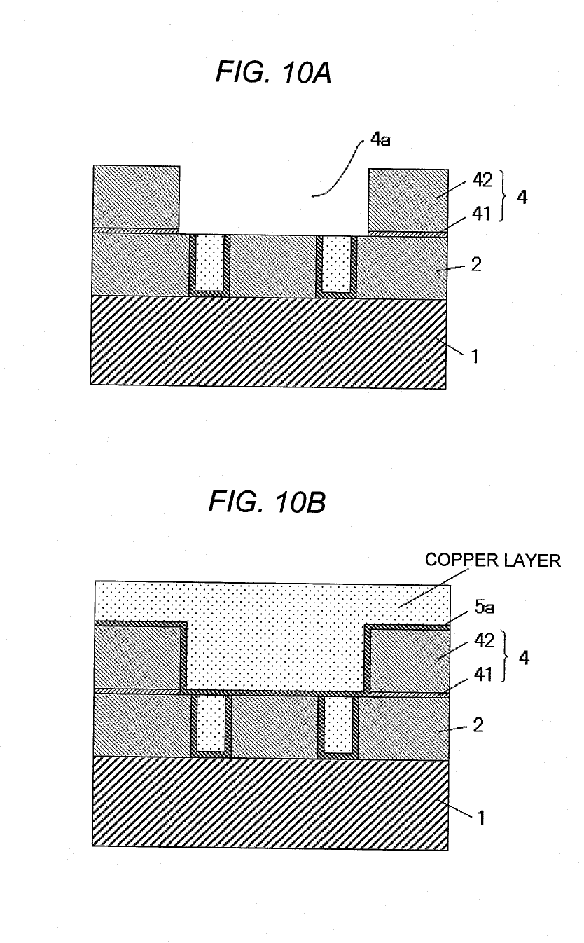

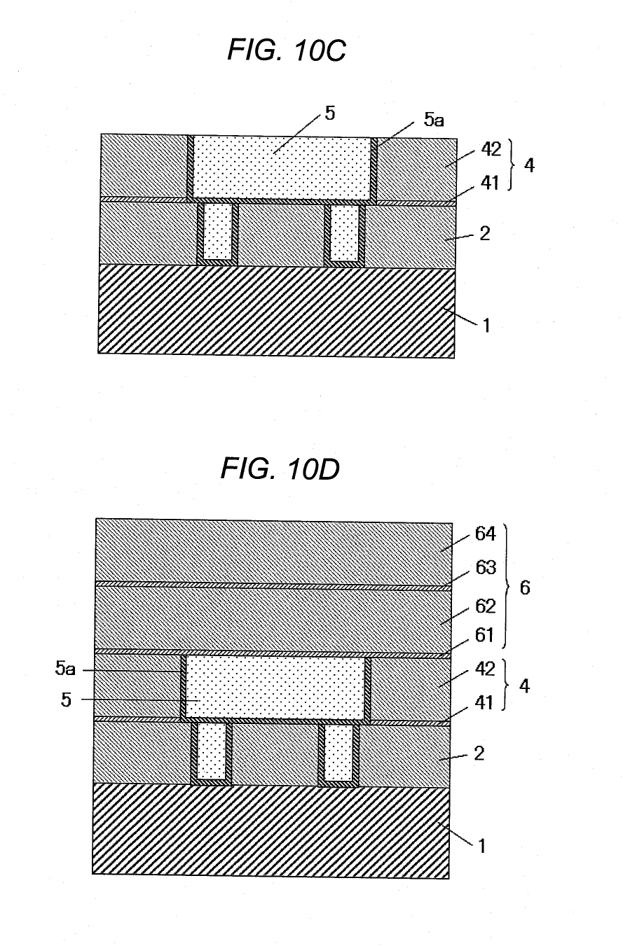

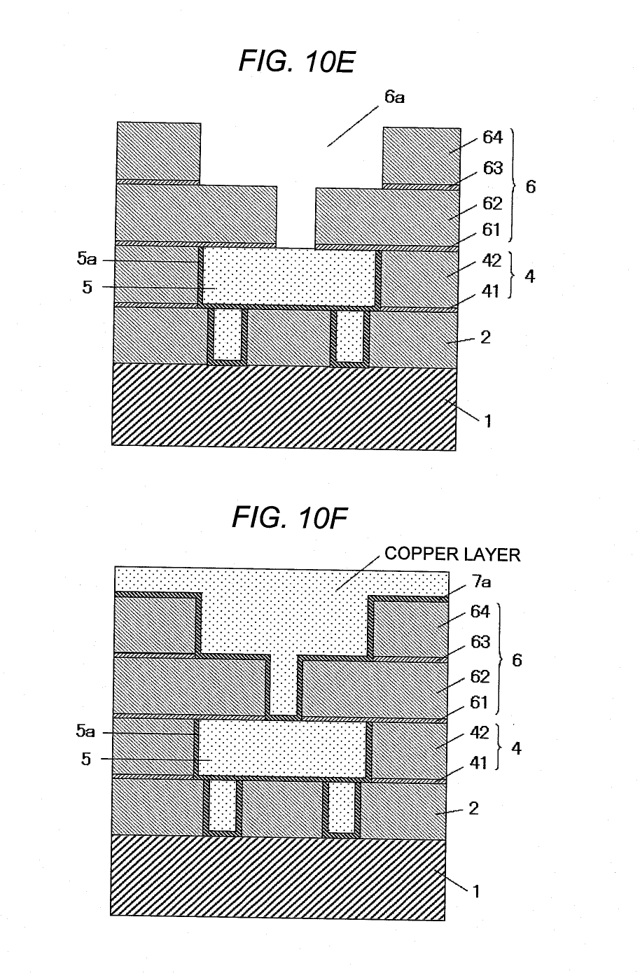

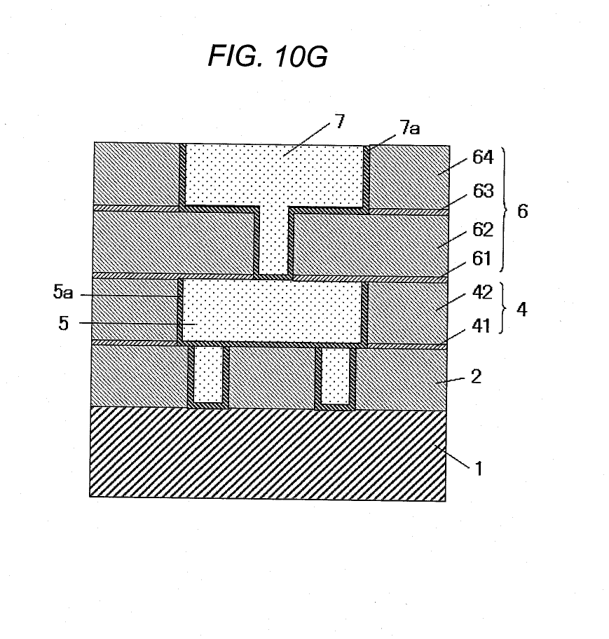

FIG. 10 is a schematic process chart explaining a method of producing semiconductor integrated-circuit devices according to the present invention, wherein the same alphanumeric character is assigned to the member that is the same as that in FIG. 1 to avoid repeating the same explanation. Furthermore, among methods of producing semiconductor integrated-circuit devices, a copper wiring forming process that uses a dual damascene process directly related to the present invention is shown.

First, there is a semiconductor substrate 1 on which a large number of circuit elements (not shown) are formed adjacent to one main surface 11 of the substrate; then, a first insulation layer 4 composed of a silicon nitride layer 41 and a silicon oxide layer 42 is deposited by a CVD (Chemical Vapor Deposition) method above the main surface 11 of the semiconductor substrate 1. Next, the silicon oxide layer 42 in the area on which wiring is to be formed is removed by etching, and then the exposed silicon nitride layer 41 is further etched to form a first trench 4a. This trench has a width of 70 nm or less and a depth within a range between 50 nm and 300 nm that is determined according to the current-carrying capacity. The silicon nitride layer 41 is used as a stopper when the silicon oxide layer 42 is etched (FIG. 10A).

Next, on a silicon oxide layer 42 including the inside of the first trench 4a, a barrier layer 5a, composed of e.g. a TaN/Ta laminated body, from several nm to 10 nm thick is deposited by a sputtering or CVD method. Copper wiring 5 is formed on this barrier layer 5a. The method is as follows: First, an extremely thin copper seed layer (not shown) is formed on the barrier layer 5a by sputtering; next, a copper plating layer thicker than the depth of the first trench 4a is formed on the copper seed layer by an electrolytic plating method using a copper sulfate plating bath and a copper electrode for the anode; then, annealing treatment is conducted wherein heating is conducted in an atmosphere selected from hydrogen, argon, and nitrogen starting at room temperature and rising to 400° C. by an infrared lamp with a heating rate of 1.3K per second, and the constant temperature of 400° C. is maintained for ten minutes (FIG. 10B).

Next, the copper layer portion that exceeds the depth of the first trench 4a is removed from the first trench 4a portion by a CMP (Chemical Mechanical Polishing) method, and the copper layer and the barrier layer 5a on the silicon oxide layer 42 are removed, so that the copper layer and the barrier layer 5a that will form the first copper wiring 5 remain only within the first trench 4a (FIG. 10C).

Then, a silicon nitride layer 61, a silicon oxide layer 62, a silicon nitride layer 63 and a silicon oxide layer 64 are sequentially deposited by a CVD method on the silicon oxide layer 42 and the first copper wiring 5. Herein, the silicon nitride layer 63 functions as an etching stopper during forming the upper part of the second trench 6a having a T-letter shape cross section, and the silicon nitride layer 61 functions as an etching stopper during forming a contact hole (leg portion of the T-letter shape) to make connections to the first copper wiring 5 (FIG. 10D). The upper part of the trench has a width of 70 nm or less and a depth within a range between 40 and 300 nm that is determined according to the current-carrying capacity.

Next, the silicon oxide layer 64, silicon nitride layer 63, and the silicon oxide layer 62 on the contact area of the first copper wiring 5 are removed by etching, and the exposed silicon nitride layer 61 is then etched to form a contact hole (leg portion of the T-letter shape of the second trench 6a).

Then, an antireflection film or a resist film (not shown) is formed on the silicon oxide layer 64 including the inside of the contact hole. Furthermore, the antireflection film or the resist film, and the silicon oxide layer 64 are etched with a mask of the resist film on which an area to form a second copper wiring 7 is left open. Subsequently, the exposed silicon nitride layer 63 is etched and the antireflection film or the resist film within the contact hole is removed to form a second trench 6a (FIG. 10E).

Next, on the silicon oxide layer 64 including the inside of the second trench 6a, a barrier layer 7a, composed of e.g. a Ta/TaN/Ta laminated body, from several nm to 10 nm thick is deposited by a sputtering or CVD method.

Then, a thin copper film that functions as a seed layer is formed on the barrier layer 7a by sputtering; and a copper layer that is thicker than the depth of the second trench 6a is formed on the entire surface of the barrier layer 7a including the second trench 6a by the same method as the first copper wiring was made; then, annealing treatment is conducted wherein heating is conducted in an atmosphere selected from hydrogen, argon, and nitrogen, starting at room temperature and rising to 400° C. by an infrared lamp with a heating rate of 1.3K per second, and then the constant temperature of 400° C. is maintained for ten minutes (FIG. 10F).

After that, the copper layer portion that exceeds the depth of the second trench 6a is removed from the second trench 6a portion by a CMP method, and the copper layer and the barrier layer 7a on the silicon oxide layer 64 are removed, so that the copper layer and the barrier layer 7a that will form the second copper wiring 7 remain only within the second trench 6a. Thus 2-layer structure copper wiring is competed (FIG. 10G).

In this example, a method of producing 2-layer structure copper wiring has been described, and a wiring structure of three layers or more can be created by repeating the processes by which the second copper wiring was formed. In this case, annealing of copper wiring can be conducted every time copper wiring is formed, or it can be conducted all at once after all of the copper wiring has been formed. In a semiconductor integrated-circuit device, a line width between the first layer and the second layer of wiring is narrow and the line width becomes wider toward the upper layer. Since the present invention aims to improve the electromigration resistance of wiring having a narrow line width as well as keep resistivity low, it is preferable that the annealing is conducted every time after forming of copper wiring in the case of narrow line width, and that the annealing is conducted all at once after forming of all of the copper wiring in the case of wide line width. Herein, the narrow line width is considered to be 70 nm or less, and the wide line width is considered to be more than 70 nm.

In the embodiments of the present invention, a combination of Ta film and TaN film was used for barrier layers 5a, 7a. The combination of film is not intended to be limited to Ta and TaN, and film combinations of other metals and nitrides of those metals can be used. Metals can include Ti (titanium), W (tungsten), Nb (niobium), Cr (chromium), and Mo (molybdenum).

The present invention has been described by taking an example of the case where a semiconductor integrated-circuit device is formed on a semiconductor wafer. However, the present invention can also be applied to a semiconductor integrated-circuit device wherein a semiconductor layer is formed on an insulated substrate, and circuit elements are formed on the semiconductor layer.

1. A method of producing a semiconductor integrated-circuit device comprising a semiconductor substrate with a circuit element formed thereon, an insulation layer formed on the main surface of said semiconductor substrate, a trench formed by at least using said insulation layer, and a copper wiring formed within said trench; said method having an annealing process wherein
said copper wiring is heated to an annealing temperature within 200° C. to 500° C. by a temperature gradient of 30K to 55K per μm between the bottom portion and the top surface, and then said annealing temperature is maintained for a prescribed time duration within one to 60 minutes.

2. The method of producing a semiconductor integrated-circuit device according to claim 1, wherein
said the heating rate to reach said annealing temperature is 1K to 10K per second.

3. The method of producing a semiconductor integrated-circuit device according to claim 2, comprising
a process wherein a wiring layer of said copper wiring is deposited within a trench of said semiconductor substrate by a plating technique, and
an annealing process wherein
said semiconductor substrate with said copper wiring layer deposited is placed in an atmosphere at room temperature, heated to an annealing temperature within 250° C. to 400° C. with a prescribed heating rate within 1K to 10K per second, and then said annealing temperature is maintained for a prescribed time duration within one minute to 10 minutes.

4. The method of producing a semiconductor integrated-circuit device according to claim 3, wherein
heating in said annealing process is conducted by irradiation by a lamp and/or laser.

5. The method of producing a semiconductor integrated-circuit device according to claim 4, wherein
heating in said annealing process is conducted by irradiation by an infrared lamp.
